(19) United States
(12) Patent Application Publication
(10) Pub. No.: US 2026/0227436 A1
(43) Pub. Date: Aug. 6, 2026

(54) INSULATION MONITORING SYSTEM COMPRISING MULTIPLE INSULATION MONITORING DEVICES, AND A METHOD FOR CONTROLLING INSULATION MONITORING DEVICES CONSTITUTING SAME SYSTEM

(71) Applicant: LS ELECTRIC CO., LTD., Anyang-si, Gyeonggi-do (KR)

(72) Inventors: Minsu PARK, Anyang-si, Gyeonggi-do (KR); Jaeshik YOON, Anyang-si, Gyeonggi-do (KR)

(21) Appl. No.: 19/150,349

(22) PCT Filed: Dec. 22, 2023
(86) PCT No.: PCT/KR2023/021483

§ 371 Date: Jul. 23, 2025

(30) Foreign Application Priority Data
Mar. 31, 2023 (KR) 10-2023-0043023

(51) Int. Cl. G01R 31/12; G01R 19/25; G01R 27/18

(52) U.S. Cl. CPC G01R 31/1272; G01R 19/2506; G01R 27/18

(57) ABSTRACT

The present disclosure comprises multiple insulation monitoring devices, each of which: maintains, in a deactivated state, a signal generation unit for applying a pulse signal to one of at least one internal line connected to a power line via a transformer; detects the reception of a notification signal from at least one other insulation monitoring device that is communicatively connected; activates the deactivated signal generation unit to apply a pulse signal to the one internal line when the notification signal is received as a result of the detection; calculates the insulation resistance between the internal line and a ground on the basis of the pulse signal applied from the activated signal generation unit; and transmits a notification signal to the at least one other insulation monitoring device that is communicatively connected; and switches the activated signal generation unit to a deactivated state.

### CROSS-REFERENCE TO RELATED APPLICATION

This application is the national phase entry of International Application No. PCT/KR2023/021483, filed on Dec. 22, 2023, which is based upon and claims priority to Korean Patent Application No. 10-2023-0043023, filed on Mar. 31, 2023, the entire contents of which are incorporated herein by reference.

### FIELD

The present disclosure relates to an insulation monitoring system including multiple insulation monitoring devices, and more particularly, to an insulation monitoring system that can avoid measurement interference between each insulation monitoring device when measuring an insulation resistance, and a control method for each insulation monitoring device.

### BACKGROUND

An insulation terra (IT) grounding method is a grounding method in which neither of the power lines is grounded, but only through an enclosure of a load. The IT grounding method has an advantage of securing a continuous operation of a system, as it allows a time period to find a location of a ground fault without stopping the operation of the system even when the ground fault occurs in one of the power lines.

Since the system can continue to operate even when a ground fault occurs in this manner, it is necessary to continuously monitor an insulation state of power lines while the system is in operation. Accordingly, the International Electro-technical Commission (IEC) 61557 standard requires the installation of an insulation monitoring device that can monitor an insulation state of power lines.

Such an insulation monitoring device (IMD) may include a pulse signal generation unit disposed between the ground and a transmission line to form a circuit between the transmission line and the ground through an insulation resistance disposed between the transmission line and the ground, and inject a square wave (pulse) signal into the formed circuit, and a detection resistor for detecting a voltage according to the square wave signal. Furthermore, when the pulse signal generation unit applies a signal (voltage: Vp) to the ground (protective earth (PE)), an insulation resistance Re may be calculated based on a signal (voltage: Vm) in which a voltage is distributed by a virtual resistance (insulation resistance Re) between an ungrounded line and the earth and an internal resistance Ri of the IMD from the applied signal Vp so as to allow an insulation state of the ungrounded line to be monitored.

Meanwhile, the pulse signal generation unit injects a pulse signal whose polarity is reversed into the circuit at regular intervals. However, when the polarity of the pulse signal is reversed, charging and discharging of an insulating capacitor occurs due to a voltage difference of the reversed pulse signal, which causes a transient phenomenon in which the voltage increases and becomes unstable, as shown in FIG. 1. The transient phenomenon is temporary, and when a predetermined period of time Ti (stabilization time period) has elapsed until the charging and discharging of the insulating capacitor is completed, the voltage is stabilized again (Vi: stabilized voltage).

Meanwhile, in the transient state, the insulation resistance and insulation capacitance components of a line to be measured are mixed and have a large error, thus making it difficult to calculate an accurate insulation resistance. Therefore, the insulation monitoring device usually waits until a transient period in which the transient phenomenon occurs has ended, and then calculates the insulation resistance while the voltage is stabilized. Therefore, when the reversal of a pulse signal occurs, the insulation monitoring device continuously performs sampling from a time point when the reversal of the pulse signal occurs until the insulation resistance is calculated, and determines whether the voltage is stabilized based on the sampled voltage signal.

Meanwhile, the use of a multi-winding transformer, such as a three-winding transformer or five-winding transformer, is increasing in addition to a two-winding transformer that converts a current of a power line into a current at a specific voltage. In the case of such a multi-winding transformer, a voltage of a power line may be converted into two or four different voltages, thus allowing one transformer to be connected to two or more different loads with different driving voltages. Therefore, a number of transformers may be reduced, thereby reducing costs.

However, when using a multi-winding transformer in this manner, insulation monitoring must be performed for each internal line connected to different loads. Accordingly, multiple insulation monitoring devices may be used simultaneously. In addition, even within the internal line, a section where a direct current flows and a section where an alternating current flows may be distinguished depending on a load connected thereto, such as an energy storage system (ESS), a battery, or a photovoltaic (PV) generator through a power conditioning system (PCS) such as an inverter or converter, and in such a case, when the internal line is distinguished into sections where currents with different components flow, insulation monitoring must be performed for each section, and accordingly, multiple insulation monitoring devices may be used simultaneously within one internal line.

However, when multiple insulation monitoring devices are used in this manner, the multiple insulation monitoring devices may each be grounded to the ground. In this case, interference may not occur if the grounding locations are sufficiently separated, but it is difficult to secure a sufficient separation distance due to spatial issues, and the multiple insulation monitoring devices may be connected to the adjacent grounds PE. Then, a voltage generated from the pulse signal generation unit of each of the multiple insulation monitoring devices may be applied to the ground PE. When a separation distance between the grounds is not sufficiently secured, multiple insulation monitoring devices may be connected to the same ground. In this case, the multiple insulation monitoring devices may share the same ground.

When multiple insulation monitoring devices are connected to the same ground in this manner, a voltage higher than the stabilized voltage Vi may be detected even when the stabilization time period Ti for a pulse voltage applied from a specific insulation monitoring device has elapsed due to a pulse voltage supplied from another insulation monitoring device. Alternatively, the stabilization time period Ti may be lengthened due to an increase in a transient state voltage. In addition, when multiple insulation monitoring devices are connected to the same ground PE, there is a problem that it is difficult to calculate an accurate insulation resistance because internal resistances of respective insulation monitoring devices are combined with an internal resistance of a specific insulation monitoring device that is calculating the insulation resistance.

Accordingly, when multiple insulation monitoring devices are connected to the same ground PE, research is being actively conducted to find a way for each insulation monitoring device to accurately calculate an insulation resistance without measurement interference between the insulation monitoring devices.

### SUMMARY

The present disclosure aims to solve the above-mentioned problems and other problems, and an aspect of the present disclosure is to provide an insulation monitoring system in which multiple insulation monitoring devices can each calculate an insulation resistance without mutual measurement interference, and a method of controlling the insulation monitoring devices constituting the system.

In order to achieve the foregoing and other objectives, according to an aspect of the present disclosure, an insulation monitoring system according to an embodiment of the present disclosure may include multiple insulation monitoring devices, each of which maintains in a deactivated state a signal generation unit that applies a pulse signal to at least one internal line connected to a power line through a transformer, and detects the reception of a preset notification signal from at least one other insulation monitoring device that is communicably connected thereto, activates, when the notification signal is received as a result of the detection, the signal generation unit in the deactivated state so as to allow a pulse signal to be applied to the one internal line, calculates an insulation resistance between the one internal line and the ground according to the pulse signal applied to the one internal line from the activated signal generation unit, and transmits, when the insulation resistance is calculated, the notification signal to the at least one other insulation monitoring device that is communicably connected thereto, and switches the activated signal generation unit back to an inactive state.

In one embodiment, the insulation monitoring device may include an interface unit that performs a communication connection with the at least one other insulation monitoring device, the signal generation unit, a signal measurement unit connected to the ground to measure a voltage according to a pulse signal generated from the activated signal generation unit from the ground, an insulation resistance calculation unit that calculates the insulation resistance based on the voltage measured by the signal measurement unit, and a control unit that receives the notification signal from one of the at least one other insulation monitoring device through the interface unit, activates the signal generation unit when the notification signal is received, controls the insulation resistance calculation unit so as to allow the insulation resistance to be calculated, transmits the notification signal to the at least one other insulation monitoring device when the insulation resistance is calculated, and switches the signal generation unit to an inactive state.

In one embodiment, the signal generation unit may include a power source circuit disposed to supply power to the signal generation unit according to the control of the control unit.

In one embodiment, the multiple insulation monitoring devices may be multiple insulation monitoring devices sharing the same ground.

In one embodiment, the multiple insulation monitoring devices may constitute a ring network in which adjacently arranged insulation monitoring devices are communicably connected to one another, wherein each of the multiple insulation monitoring devices activates, when the notification signal is received from a first insulation monitoring device adjacent thereto, a signal generation unit in a deactivated state to calculate an insulation resistance, switches, when the insulation resistance is calculated, the activated signal generation unit to a deactivated state, and transmits the notification signal to a second insulation monitoring device adjacent thereto.

In one embodiment, the multiple insulation monitoring devices may constitute a bus network that shares one transmission line and is communicably connected to one another through the shared transmission line, wherein each of the multiple insulation monitoring devices receives the notification signal broadcast by one of the other insulation monitoring devices through the shared transmission line, calculates an insulation resistance by activating a signal generation unit in a deactivated state based on a time period elapsed from a time point at which the previous insulation resistance was calculated and a time point at which the notification signal was received, and switches, when the insulation resistance is calculated, the activated signal generation unit to a deactivated state, and broadcasts the notification signal to at least one other insulation monitoring device through the shared transmission line.

In one embodiment, each of the multiple insulation monitoring devices may broadcast a request signal indicating that the calculation of an insulation resistance is necessary to at least one other insulation monitoring device based on whether a time period elapsed from a time point at which the previous insulation resistance was calculated is above a threshold time period, and determine, when the notification signal is received, whether to activate the signal generation unit by comparing a time point at which the request signal was broadcast with a time point at which the request signal was received from at least one other insulation monitoring device until the notification signal is received.

In one embodiment, the multiple insulation monitoring devices may constitute a star network in which each of the multiple insulation monitoring devices is connected to a preset master device, wherein the master device determines an insulation resistance calculation sequence of each of the multiple insulation monitoring devices according to a preset priority, receives the notification signal from one insulation monitoring device whose insulation resistance has been calculated, and transmits the received notification signal to an insulation monitoring device in a next sequence of the one insulation monitoring device according to the determined insulation resistance calculation sequence.

In one embodiment, the master device may be one of the multiple insulation monitoring devices.

In one embodiment, the transformer may be a multi-winding transformer that links multiple different internal lines to a single power line, wherein the multiple insulation monitoring devices are devices that monitor insulation states between the ground and multiple different internal lines connected to different windings of the multi-winding transformer.

In one embodiment, the transformer may be a multi-winding transformer that links multiple different internal lines to a single power line, wherein the multiple insulation monitoring devices are devices that monitor insulation states between different points of an internal line connected to the same winding of the multi-winding transformer and the ground.

In one embodiment, the insulation monitoring device may include a changeover unit that separates the insulation monitoring device from the internal line or connects the insulation monitoring device separated from the internal line to the internal line, an interface unit that performs a communication connection with the at least one other insulation monitoring device, the signal generation unit, a signal measurement unit connected to the ground to measure a voltage according to a pulse signal generated from the activated signal generation unit from the ground, an insulation resistance calculation unit that calculates the insulation resistance based on the voltage measured by the signal measurement unit, and a control unit that receives the notification signal from one of the at least one other insulation monitoring device through the interface unit, controls, when the notification signal is received, the changeover unit to connect the separated insulation monitoring device to the internal line, and activate the signal generating unit, controls, when the signal generating unit is activated, the insulation resistance calculation unit so as to allow the insulation resistance to be calculated, transmits, when the insulation resistance is calculated, the notification signal to the at least one other insulation monitoring device, and controls the changeover unit so as to switch the signal generation unit to an inactive state and allow the insulation monitoring device to be separated from the internal line.

In one embodiment, the changeover unit may be disposed to separate the signal generation unit from the internal line or reconnect the signal generation unit separated from the internal line back to the internal line, or to separate the signal measurement unit from the ground or to reconnect the signal measurement unit separated from the ground to the ground.

In one embodiment, the changeover unit may have a first side disposed on a side of the signal generation unit or signal measurement unit, and a second side disposed on a side of the internal line or grounding, and may include an electronic contactor in which the first side and the second side are in contact with each other when a current is supplied according to the control of the control unit, and the first side and the second side are separated from each other when the current supply is interrupted.

In order to achieve the foregoing and other objectives, according to an aspect of the present disclosure, a method of controlling one of multiple insulation monitoring devices constituting an insulation monitoring system according to an embodiment of the present disclosure may include switching a signal generation unit that applies a pulse signal to one of at least one internal line linked to a power line through a transformer to a deactivated state, maintaining the signal generation unit in a deactivated state until a preset notification signal is received from one of at least one other insulation monitoring device constituting the insulation monitoring system that are connected to one another while the signal generation unit is in a deactivated state, switching, when the notification signal is received, the signal generation unit to an activated state, calculating an insulation resistance between the one internal line and the ground according to the pulse signal applied to the one internal line from the activated signal generation unit, transmitting, when the insulation resistance is calculated, the notification signal to the at least one other insulation monitoring device that is communicably connected thereto, and repeating the steps of switching, when the notification signal is transmitted, the signal generation unit to a deactivated state, maintaining the signal generation unit in a deactivated state, activating the signal generation unit according to whether the notification signal is received, calculating the insulation resistance, and transmitting the notification signal.

In one embodiment, the transformer may be a multi-winding transformer that links multiple different internal lines to a single power line, wherein the multiple insulation monitoring devices are devices that monitor insulation states between different points of an internal line connected to the same winding of the multi-winding transformer and the ground.

In one embodiment, the switching of the signal generation unit to a deactivated state may further include separating the insulation monitoring device from the internal line, and the switching of the signal generation unit to an active state may further include reconnecting the insulation monitoring device, which has been separated from the internal line, to the internal line.

In one embodiment, the notification signal may be transmitted, when an insulation resistance is calculated from one insulation monitoring device, to an insulation monitoring device in a next sequence of the one insulation monitoring device based on an insulation resistance calculation sequence according to a priority set for each of the multiple insulation monitoring devices, and the priority may be determined according to a time period elapsed from a time point at which each insulation monitoring device lastly calculated the insulation resistance.

The effects of an insulation monitoring system and a method of controlling insulation monitoring devices according to the present disclosure will be described as follows.

According to at least one of embodiments of the present disclosure, the present disclosure may limit the driving of a signal generation unit that generates a pulse voltage during a time period in which insulation monitoring devices connected to different internal lines to calculate an insulation resistance do not calculate the insulation resistance, thereby preventing measurement interference that can occur when calculating the insulation resistance of another insulation monitoring device. Therefore, there is an effect in which multiple insulation monitoring devices can each calculate an insulation resistance without mutual measurement interference.

In addition, according to at least one of embodiments of the present disclosure, the present disclosure may transmit a signal notifying that the calculation of an insulation resistance is completed to at least one another insulation monitoring device when each insulation resistance calculation device calculates the insulation resistance, and transmit a signal notifying that calculation of the insulation resistance is necessary to at least one still another insulation monitoring device according to a time period elapsed from a time point at which the previous insulation resistance was calculated, thereby allowing multiple insulation monitoring devices to autonomously determine a time point at which the insulation resistance is calculated among one another. Therefore, there is an effect in which multiple insulation monitoring devices can each calculate an insulation resistance without mutual measurement interference.

In addition, the present disclosure may open a circuit for insulation monitoring in the case of insulation monitoring devices connected to the same internal line, thereby having an effect of preventing, when calculating an insulation resistance, its own internal resistance from being combined with the internal resistance of the other insulation monitoring device.

### BRIEF DESCRIPTION OF THE DRAWINGS

FIG. 1 is an exemplary diagram showing an example of a voltage change detected by an insulation monitoring device according to a polarity change of a pulse voltage when calculating an insulation resistance.

FIG. 2 is an exemplary diagram showing an insulation monitoring system in which insulation monitoring devices connected to different internal lines are connected to the same ground according to an embodiment of the present disclosure.

FIG. 3 is a block diagram showing a configuration of an insulation monitoring device constituting an insulation monitoring system according to an embodiment of the present disclosure.

FIG. 4 is a conceptual diagram for explaining an operation of controlling an interface unit so as to allow a control unit of an insulation monitoring device in an insulation monitoring system according to an embodiment of the present disclosure to receive and output an insulation resistance calculation notification signal.

FIG. 5 is an exemplary diagram for explaining a combined resistance according to an internal resistance of another insulation monitoring device resistance, a resistance of a transformer, and an insulation resistance, in an insulation monitoring system consisting of two insulation monitoring devices connected to different internal lines.

FIGS. 6A and 6B are an example of a network formed by insulation monitoring devices constituting an insulation monitoring system according to an embodiment of the present disclosure, and a flowchart showing an operation process for calculating, by each insulation monitoring device, an insulation resistance.

FIGS. 7A and 7B are an example of a different network formed by insulation monitoring devices constituting an insulation monitoring system according to an embodiment of the present disclosure, and a flowchart showing a different operation process for calculating, by each insulation monitoring device, an insulation resistance.

FIGS. 8A to 9B are exemplary diagrams showing an example of a network configuration in which the calculation of an insulation resistance and the driving of a signal generation unit are limited by a server or one insulation monitoring device in an insulation monitoring system according to an embodiment of the present disclosure.

FIGS. 10A and 10B are exemplary diagrams showing an insulation monitoring system in which insulation monitoring devices that calculate an insulation resistance at different locations of the same internal line are connected to the same ground.

FIG. 11 is a block diagram showing a configuration of an insulation monitoring device further including a changeover element that can be changed over, when connected to one internal line, from the internal line to avoid measurement interference with other insulation monitoring devices.

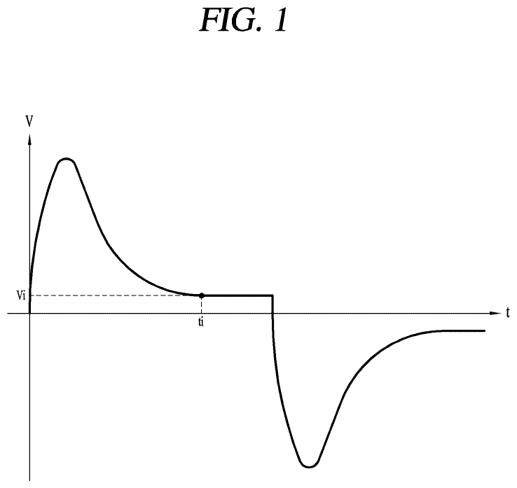

### DETAILED DESCRIPTION

It should be noted that technical terms used herein are merely used to describe a specific embodiment, but not to limit the present disclosure. In addition, a singular expression used herein may include a plural expression unless clearly defined otherwise in the context. A suffix “module” or “part” used for elements disclosed in the following description is merely intended for easy description of the specification, and the suffix itself is not intended to have any special meaning or function.

As used herein, terms such as “comprise” or “include” should not be construed to necessarily include all elements or steps described herein, and should be construed not to include some elements or some steps thereof, or should be construed to further include additional elements or steps.

In addition, in describing technologies disclosed herein, when it is determined that a detailed description of known technologies related thereto may unnecessarily obscure the subject matter disclosed herein, the detailed description will be omitted.

In addition, the accompanying drawings are provided only for a better understanding of the embodiments disclosed in this specification and are not intended to limit technical concepts disclosed in this specification, and therefore, it should be understood that the accompanying drawings include all modifications, equivalents and substitutes within the concept and technical scope of the present disclosure. In addition, not only respective embodiments described below, but also combinations of embodiments may, of course, be included within the concept and technical scope of the present disclosure as modifications, equivalents or substitutes.

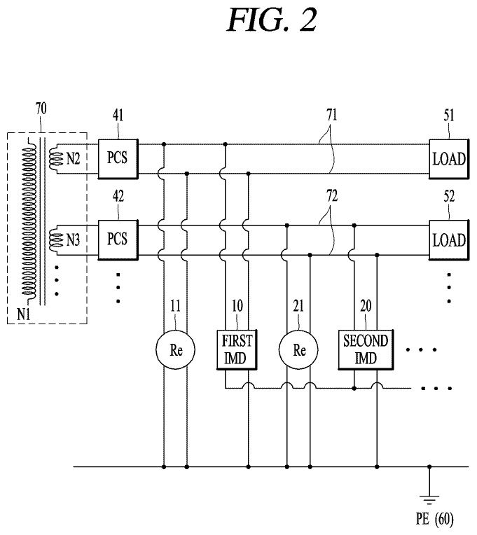

FIG. 2 is an exemplary diagram showing an insulation monitoring system in which insulation monitoring devices connected to different internal lines are connected to the same ground according to an embodiment of the present disclosure.

Referring to FIG. 2, FIG. 2 shows an example in which power lines of a system are connected to a multi-winding transformer 70. In this case, the multi-winding transformer 70 may convert a power source of the system into multiple different types of power sources. In this case, since one transformer can supply power to loads that require different types of power sources, costs may be reduced, and since there is no need to install multiple transformers, the transformer installation space may be reduced so as to allow an efficient use of space.

Meanwhile, the multi-winding transformer 70 may be linked to circuits as many times as a number of windings excluding a primary winding. For example, in the case of a three-winding transformer, separate circuits may be linked to secondary and tertiary windings. Additionally, in the case of a five-winding transformer, separate circuits may be linked to secondary to quintic windings. Therefore, in the case of a three-winding transformer, two different circuits may be linked to a power source of the system, and in the case of a five-winding transformer, four different circuits may be linked to a power source of the system. In the following description, electrical lines of circuits linked to respective windings of the multi-winding transformer 70 are referred to as ‘internal lines’ to distinguish them from the power lines of the system.

Examining them in detail, a first internal line 71 may be linked to a second winding N2 of the multi-winding transformer 70. Furthermore, a second internal line 72 may be linked to a third winding N3 of the multi-winding transformer 70. Furthermore, the first internal line 71 and the second internal line 72 may be separate circuits. Additionally, each internal line may carry currents at different voltages.

As shown in FIG. 2, when multiple internal lines 71, 72 that are connected to different loads 51, 52 and constitute separate circuits are connected to power lines of a system by the multi-winding transformer 70, monitoring of the insulation state of each internal line 71, 72 is required. Therefore, insulation monitoring devices 10, 20 capable of monitoring an insulation resistance may be disposed between the ground PE 60 and each internal line 71, 72. Here, the first insulation monitoring device 10 may be connected to the first internal line 71 to monitor the insulation state of the first internal line 71 through an insulation resistance between the first internal line 71 and the ground PE 60. In addition, the second insulation monitoring device 20 may be connected to the second internal line 72 to monitor the insulation state of the second internal line 72 through an insulation resistance between the second internal line 72 and the ground PE 60.

However, a grounding locations of the first insulation monitoring device 10 and a grounding location of the second insulation monitoring device 20 may be within a distance that is not sufficiently far apart to ignore measurement interference. That is, locations where each insulation monitoring device is grounded may be adjacent to each other. In this case, the first insulation monitoring device 10 and the second insulation monitoring device 20, which are multiple insulation monitoring devices connected to the same ground PE 60, may be insulation monitoring devices that share the same ground PE 60. In this case, the first insulation monitoring device 10 and the second insulation monitoring device 20 may constitute an insulation monitoring system that requires measurement avoidance through mutual agreement in measuring an insulation resistance.

Meanwhile, in an insulation monitoring system according to an embodiment of the present disclosure, which includes multiple insulation monitoring devices connected to the same ground PE 60, the multiple insulation monitoring devices may be connected to one another through wired or wireless communication for mutual consultation.

In this case, the multiple insulation monitoring devices may output a calculation notification signal notifying the calculation of an insulation resistance to another insulation monitoring device through the wireless or wired communication, or receive a calculation notification signal notifying that an insulation resistance has been calculated from another insulation monitoring device. In this case, each insulation monitoring device may synchronize the driving of a signal generation unit that generates a pulse signal according to the calculation notification signal.

That is, each of the multiple insulation monitoring devices constituting the insulation monitoring system may limit the driving of its own pulse signal generation unit or initiate the driving of the pulse signal generation unit depending on whether a calculation notification signal notifying that the calculation of an insulation resistance has been completed is received from another insulation monitoring device. Furthermore, when the pulse signal generation unit is driven, an insulation resistance may be calculated based on a pulse voltage output from the pulse signal generation unit. Furthermore, when the insulation resistance is calculated, a signal (calculation notification signal) notifying that the calculation of the insulation resistance has been completed may be output to another insulation monitoring device. Here, depending on a form in which the multiple insulation monitoring devices constituting the insulation monitoring system are connected, that is, a network form, an insulation monitoring device to receive the output calculation notification signal may or may not be designated in advance.

As an example, a specific insulation monitoring device constituting the insulation monitoring system according to the network form may receive the output calculation notification signal from a designated first insulation monitoring device. Furthermore, when the pulse signal generation unit is driven to complete the calculation of the insulation resistance upon receipt of the calculation notification signal, the calculation output notification signal may be transmitted to a designated second insulation monitoring device. Here, the designated first and second insulation monitoring devices may be different insulation monitoring devices, or may be the same insulation monitoring devices, depending on the type of network to which the insulation monitoring devices are connected.

Alternatively, a specific insulation monitoring device constituting the insulation monitoring system according to the network form may determine whether it is a time point that is required to calculate an insulation resistance from a time point at which the previous insulation resistance was calculated, and broadcast, when the calculation of the insulation resistance is required, a request signal notifying that the calculation of the insulation resistance is required. Furthermore, when a calculation notification signal that is broadcast from another insulation monitoring device constituting the insulation monitoring system is received, the device may determine the order of a request signal broadcast by itself and a request signal received from the other insulation monitoring device, and wait until the calculation notification signal is received again or initiate the driving of the pulse signal generation unit to calculate the insulation resistance. Furthermore, when the insulation resistance is calculated, a calculation notification signal may be broadcast to at least one other insulation monitoring device constituting the insulation monitoring system, thereby allowing the other insulation monitoring device to calculate the insulation resistance.

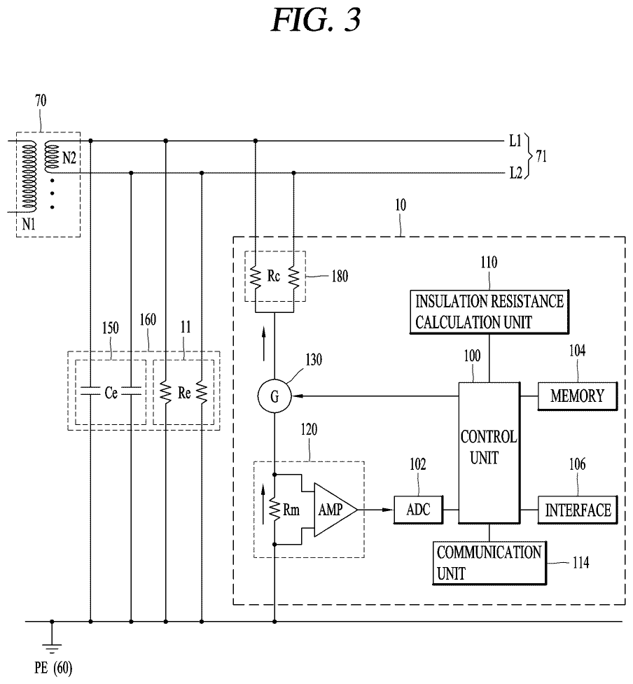

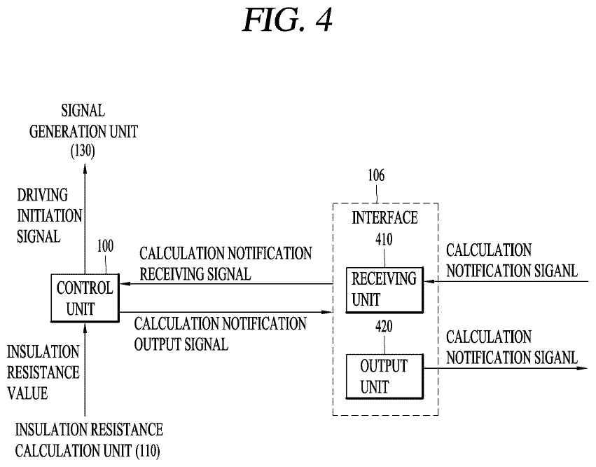

FIG. 3 is a block diagram showing a configuration of one (insulation monitoring device 10) of multiple insulation monitoring devices constituting an insulation monitoring system according to an embodiment of the present disclosure. Furthermore, FIG. 4 is a conceptual diagram for explaining an operation of controlling an interface 106 so as to allow a control unit 100 of an insulation monitoring device in an insulation monitoring system according to an embodiment of the present disclosure to receive and output an insulation resistance calculation notification signal as described above.

First, referring to FIG. 3, an insulation monitoring device 10 according to an embodiment of the present disclosure may include a coupler resistor Rc 180 connected to each of power lines L1, L2 of an internal line 71, a signal generation unit 130 that generates a pulse signal for applying a pulse voltage to the internal line 71 through the coupler resistor 180, a signal measurement unit 120 including a detection resistor Rm connected to the ground PE 60, an analog digital converter (ADC) 102 connected to the signal measurement unit 120 to convert a voltage measured by the signal measurement unit 120 into a digital value, a control unit 100 that controls other elements connected thereto, controls an overall operation of the insulation monitoring device 10, and receives the converted digital value from the ADC 102 to detect a steady-state voltage according to the applied pulse signal, and an insulation resistance calculation unit 110 that calculates a magnitude of an insulation resistance 11 based on the steady-state voltage detected by the control unit 100. Furthermore, it may include a memory 104 in which various data input to or output from the control unit 100 are stored, and an interface 106 that performs a communication connection with at least one other insulation monitoring device or other apparatus.

Meanwhile, in FIG. 3, an example is shown in which the internal line 71 is a single phase, but the internal line 71 may, of course, also be multi-phase. As an example, the internal line 71 may be three phases (R, S, T). In this case, the coupler resistance 180 may consist of resistances respectively disposed on the multi-phase power lines, for example, R, S and T lines in the case of three phases.

The elements shown in FIG. 3 are not essential for implementing the insulation monitoring device 10, and thus the insulation monitoring device 10 described in this specification may have more or fewer elements than those listed above.

Examining the insulation monitoring device 10 in more detail, first, the signal generation unit 130 may generate a pulse signal having a positive (+) voltage or a negative (−) voltage according to the control of the control unit 100. For example, the signal generation unit 130 may apply a signal having a positive voltage of a predetermined magnitude to the internal line 71 according to the control of the control unit 100. Additionally, after a predetermined time period has elapsed, a signal having a negative voltage of the same magnitude may be applied to the internal line 71 according to the control of the control unit 100. Accordingly, a signal in which positive and negative voltages alternate at regular intervals, that is, a pulse signal, may be applied to the internal line 71 according to the control of the control unit 100.

Meanwhile, as shown in FIG. 3, an insulation resistor Re 11 and an insulation capacitor 150 may be disposed between the internal line 71 and the ground PE 60. Furthermore, the internal line 71 and the ground PE 60 may be connected to each other through the insulating resistor 11 and the insulating capacitor 150. Accordingly, a circuit may be configured in which the internal line 71 and the ground PE 60 are connected through the insulating capacitor 150, the insulating resistor 11, and the insulating monitoring device 10. In this case, the capacitor 150 may generate an insulation impedance 160 between the internal line 71 and the ground 60 together with the insulation resistance 11.

Then, a pulse signal applied from the signal generation unit 130 to the internal line 71 may be input to the signal measurement unit 120 through the circuit configured between the internal line 71 and the ground 60. Here, the signal measurement unit 120 may include a detection resistor Rm, and may detect a voltage of the pulse signal applied to the internal line 71 according to the insulation resistance 11 based on a voltage across both ends of the detection resistor Rm. Furthermore, the voltage may be amplified through an amplifier and applied to the ADC 102.

Then, the ADC 102 may convert an analog voltage detected by the signal measurement unit 120 into a digital value. Furthermore, a voltage converted into the converted digital value may be input to the control unit 100. Then, when a steady-state voltage according to the applied pulse signal is detected, the control unit 100 may apply the detected steady-state voltage to the insulation resistance calculation unit 110.

Meanwhile, the insulation resistance calculation unit 110 may calculate a magnitude of the insulation resistance 11 between the internal line 71 and the ground PE 60 based on the steady-state voltage applied from the control unit 100 according to the control of the control unit 100. To this end, the insulation resistance calculation unit 110 may calculate a voltage according to the pulse signal based on the detected steady-state voltage, and may calculate a magnitude of the insulation resistance 11 based on the calculated voltage.

Meanwhile, the memory 104 stores data that supports various functions of the insulation monitoring device 10. The memory 104 may store data and commands for an operation of the insulation monitoring device 10. Additionally, data input to the control unit 100 and data output from the control unit 100 may be temporarily or permanently stored in the memory 104.

Furthermore, the interface 106 may include various elements for interaction with a user. As an example, the interface 106 may have a display unit including a display part, and various data according to the operation of the insulation monitoring device 10 may be displayed through the display unit. For example, the display unit may display information related to the insulation resistance calculated by the insulation resistance calculation unit 110. Meanwhile, since the insulation monitoring device 10 continuously calculates a magnitude of the insulation resistance, the display unit may display a change in the magnitude of the insulation resistance in real time by indicating the magnitude of the insulation resistance over time in the form of a graph.

Additionally, the interface 106 may include at least one input portion for accepting an input of the user. As an example, the input unit may be disposed to include at least one hardware key or touch key. Alternatively, when the display unit is implemented in the form of a touch screen, the display unit may also be used as the input unit.

In addition, the interface 106 may further include a communication module that performs wireless or wired communication connection with at least one other insulation monitoring device.

FIG. 4 is a conceptual diagram for explaining an operation of controlling an interface 106 so as to allow a control unit 100 of an insulation monitoring device in an insulation monitoring system according to an embodiment of the present disclosure to receive and output an insulation resistance calculation notification signal as described above.

Referring to FIG. 4, the interface 106 may include a receiving unit 410 for receiving a notification signal (insulation resistance calculation completion notification signal, hereinafter referred to as a calculation notification signal) transmitted from at least one other insulation monitoring device, and an output unit 420 for outputting the calculation notification signal for notifying the completion of insulation resistance calculation to at least one other insulation monitoring device under the control of the control unit 100 when an insulation resistance is calculated by the insulation resistance calculation unit 110.

Meanwhile, the control unit 100 may control other elements connected thereto, and control an overall operation of the insulation monitoring device 10 according to an embodiment of the present disclosure.

First, the control unit 100 may control the signal generation unit 130 according to a calculation notification signal received from another insulation monitoring device through the interface 106. In more detail, the control unit 100 may limit the driving of the signal generation unit 130 until a calculation notification signal notifying that the insulation resistance has been calculated is received from another insulation monitoring device. In this case, the signal generation unit 130 may maintain a state in which no pulse signal is generated.

To this end, the control unit 100 may interrupt power supplied to the signal generation unit 130 or control the signal generation unit 130 to maintain an inactive state in which the signal generation unit 130 does not generate a pulse signal.

For example, the signal generation unit 130 may be provided with a power source circuit that is controlled to supply power to the signal generation unit 130 according to the control of the control unit 100. In this case, the control unit 100 may control the power source circuit to interrupt power supplied to the signal generation unit 130 to limit the driving of the signal generation unit 130. Then, a pulse signal flow into the internal line 71 may be stopped.

Alternatively, the signal generation unit 130 may be disposed so as to allow an operation state to be transitioned to a sleep or standby state in which a pulse signal is not generated under the control of the control unit 100. In this case, the signal generation unit 130 may be transitioned to an inactive state, that is, the sleep or standby state, under the control of the control unit 100, and when transitioned to the sleep or standby state, the generation of the pulse signal may be stopped. Therefore, the pulse signal flow into the internal line 71 may be stopped.

When the inflow of the pulse signal is stopped as described above, only a voltage of the pulse signal applied to the internal line from another insulation monitoring device in which the signal generation unit is activated may flow into the ground PE 60. Therefore, even if multiple insulation monitoring devices are connected to the same ground PE 60, an insulation resistance may be calculated only by the pulse voltage applied from one of the multiple insulation monitoring devices. Therefore, measurement interference between multiple insulation resistance devices may be prevented.

In addition, the sleep state or standby state may be an operation state that consumes less power than a normal operation state. Additionally, power consumption of the insulation monitoring device may also be reduced when power supplied to the signal generation unit is interrupted. Therefore, power consumption in the insulation monitoring device may be saved by limiting the driving of unnecessary signal generation units.

Meanwhile, when a calculation notification signal is output from another insulation monitoring device, the control unit 100 may receive a calculation notification signal output from the other insulation monitoring device through the interface 106. In this case, the calculation notification signal may be a signal notifying that another insulation monitoring device that outputs the calculation notification signal has completed the calculation of the insulation resistance. Furthermore, when a signal (calculation notification signal) notifying that the calculation of the insulation resistance has been completed is received from another insulation monitoring device in this manner, the control unit 100 may switch the signal generation unit 130 to an activated state upon receipt of the calculation notification signal.

When the signal generation unit 130 is activated, the signal generation unit 130 may apply a pulse signal to the internal line 71. Then, a voltage according to the pulse signal applied to the internal line 71 may flow into the ground PE 60 through the insulating capacitor 150 and the insulation resistor 11 disposed between the internal line 71 and the ground PE 60. Furthermore, based on a voltage detected through the ADC 102, if it is determined that the voltage has stabilized by escaping from a transient state due to charging and discharging of the insulating capacitor 150, the insulation resistance calculation unit 110 may be controlled to calculate the insulation resistance 11 based on the stabilized voltage, that is, the steady-state voltage.

Furthermore, when the insulation resistance is calculated by the insulation resistance calculation unit 110, the control unit 100 may control the interface 106 so as to allow a calculation notification signal for notifying that itself, that is, the insulation monitoring device 10, has completed the calculation of the insulation resistance to be output to another insulation monitoring device. Furthermore, at the same time, the signal generation unit 130 may be switched back to a deactivated state so as not to interfere with the insulation resistance measurement of the other insulation monitoring devices. Furthermore, the signal generation unit 130 may be maintained in a deactivated state until a calculation notification signal is received again from another insulation monitoring device.

Meanwhile, in the case of multiple insulation monitoring devices connected to the same ground, the internal resistance Rm of another insulation monitoring device for measuring an insulation resistance may be combined with the insulation resistance 11 between the internal line 71 and the ground PE 60.

However, as shown in FIG. 2, when respective insulation monitoring devices are connected to different internal lines separated from each other by the multi-winding transformer 70, the internal resistance of each insulation monitoring device may be ignored due to the internal resistance of the multi-winding transformer 70.

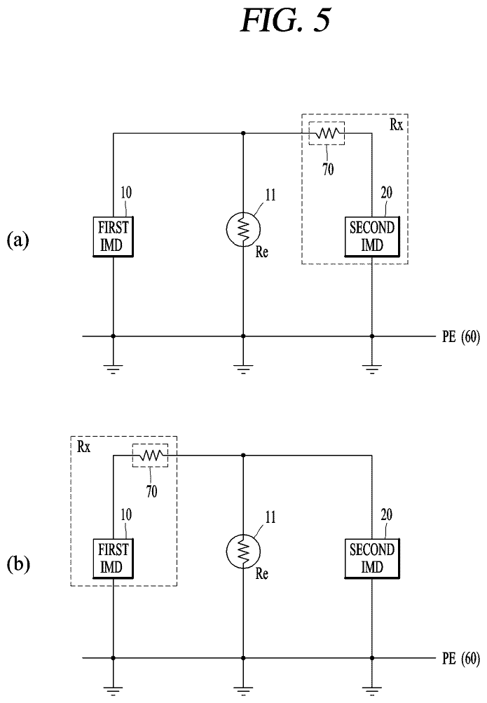

FIG. 5 is an exemplary diagram for explaining a combined resistance according to an internal resistance of another insulation monitoring device resistance, a resistance of a transformer, and an insulation resistance, in an insulation monitoring system consisting of two insulation monitoring devices connected to different internal lines as described above.

First, referring to (a) and (b) of FIG. 5, (a) and (b) of FIG. 5 show examples of a first insulation monitoring device 10 and a second insulation monitoring device 20 for calculating an insulation resistance Re 11 or 21 between the multi-winding transformer 70 and different internal lines separated by the multi-winding transformer 70 and the ground PE 60.

First, referring to (a) of FIG. 5, (a) of FIG. 5 shows a configuration of a circuit in which the second insulation monitoring device 20 is connected through the multi-winding transformer 70 when the first insulation monitoring device 10 calculates the first insulation resistance 11 of the first internal line 71. In this case, the first insulation monitoring device 10 may reverse-calculate the first insulation resistance 11 based on a current value of a pulse signal, and a resistance in which a resistance of the multi-winding transformer 70 and an internal resistance Rm of the second insulation monitoring device 20 are combined, from a stabilized voltage measured from the signal measurement unit 120.

However, a resistance Rx of the multi-winding transformer 70 is very large, reaching several tens of mega ohms, whereas the internal resistance Rm of the second insulation monitoring device 20 is very small, reaching several thousand ohms. Therefore, a sum of the resistance Rx of the multi-winding transformer 70 and the internal resistance Rm of the second insulation monitoring device 20 may converge to the resistance Rx of the multi-winding transformer 70.

Meanwhile, the first insulation resistance Re 11 is also only several thousand ohms, so it is very small compared to the resistance Rx of the multi-winding transformer 70. Therefore, when the resistances are combined, it converges to a small-sized resistance according to a resistance combination formula in the following mathematical expression. Therefore, when the resistance Rx of the multi-winding transformer 70 and the internal resistance Rm of the second insulation monitoring device 20 are combined, the internal resistance Rm of the second insulation monitoring device 20 may be ignored.

$$Rt = \frac{Re \times Rx}{Re + Rx} ∴ Re ≪ Rx ⇒ Rt ≃ Re , and Rx ≪ Re ⇒ Rt ≃ Rx \qquad [ Equation 1 ]$$

Here, Rt is a combined resistance of a resistance Re and a resistance Rx.

Meanwhile, referring to (b) of FIG. 5, (b) of FIG. 5 shows a configuration of a circuit in which the first insulation monitoring device 10 is connected through the multi-winding transformer 70 when the second insulation monitoring device 20 calculates the second insulation resistance 21 of the second internal line 72. In this case, the second insulation monitoring device 20 may reverse-calculate the second insulation resistance 21 based on a current value of a pulse signal, and a resistance in which a resistance of the multi-winding transformer 70 and an internal resistance Rm of the first insulation monitoring device 10 are added, from a stabilized voltage detected from the signal measurement unit 120.

As described above, the resistance Rx of the multi-winding transformer 70 is very large, reaching several tens of mega ohms, whereas the internal resistance Rm of the first insulation monitoring device 10 is very small, reaching several thousand ohms. Therefore, a sum of the resistance Rx of the multi-winding transformer 70 and the internal resistance Rm of the first insulation monitoring device 10 may converge to the resistance Rx of the multi-winding transformer 70.

Meanwhile, the second insulation resistance Re 21 is also only several thousand ohms, so it is very small compared to the resistance Rx of the multi-winding transformer 70. Therefore, a combined resistance of the resistance Rx of the multi-winding transformer 70 and the second insulation resistance 21 may converge to the second insulation resistance 21.

Therefore, as shown in FIG. 2, when other insulation monitoring devices connected to the same ground PE 60 are connected to different internal lines separated by the multi-winding transformer 70, an insulation monitoring device according to an embodiment of the present disclosure may calculate an insulation resistance Re by ignoring the resistance Rx of the multi-winding transformer 70 and the internal resistance Rm of the other insulation monitoring devices.

Meanwhile, even if the resistance Rx of the multi-winding transformer 70 and the internal resistance Rm of other insulation monitoring devices can be ignored as described above, since multiple insulation monitoring devices are connected to the same ground 60, a pulse voltage applied from the signal generation unit of each insulation monitoring device may cause measurement interference at the ground 60.

Accordingly, multiple insulation monitoring devices constituting an insulation monitoring system according to an embodiment of the present disclosure may be connected to one another to configure a network, and measurement interference between the insulation monitoring devices may be avoided through exchange of insulation resistance calculation notification signals through the network.

In the following description, a network configured by each insulation monitoring device constituting an insulation monitoring system according to an embodiment of the present disclosure and operational processes that limits the driving of a signal generation unit so as to allow measurement interference to be avoided between one another according to the form of the network will be examined in detail with reference to multiple exemplary diagrams and multiple flowcharts.

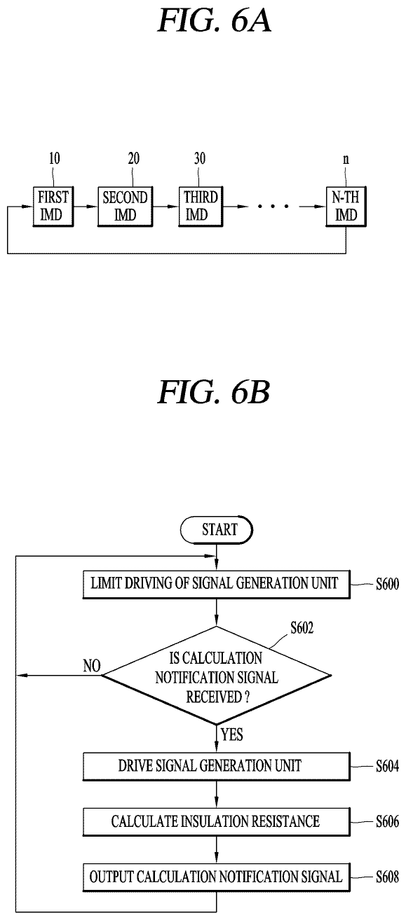

First, FIG. 6A shows an example in which multiple insulation monitoring devices constituting the insulation monitoring system configure a ring-structured network topology through serial communication. Furthermore, FIG. 6B is a flowchart showing an operation process of controlling, by each insulation monitoring device, the driving of a signal generation unit and calculating an insulation resistance based on a notification signal (a calculation notification signal notifying that an insulation resistance has been calculated) received from another insulation monitoring device when a ring network topology is configured in this manner.

First, referring to FIG. 6A, FIG. 6A shows an example in which multiple insulation monitoring devices constituting the insulation monitoring system are respectively connected to one another through serial communication to configure a ring-shaped network. In this case, for each insulation monitoring device, an insulation monitoring device that will receive the calculation notification signal may be designated in advance, and another insulation monitoring device that will output a calculation notification signal when calculating an insulation resistance may also be designated in advance.

Therefore, a sequence in which the insulation resistance is calculated may be determined for each insulation monitoring device, and each insulation monitoring device may sequentially calculate the insulation resistance according to the determined sequence. In this case, an insulation resistance calculation sequence set for the each insulation monitoring device may be determined according to a placement location, that is, an address, of the insulation monitoring device. Alternatively, it may be a sequence determined by a preset measurement priority.

Meanwhile, FIG. 6B is a flow chart showing an operation process of controlling, by the control unit of each insulation monitoring device, the driving of the signal generation unit and calculating an insulation resistance based on the calculation notification signal received from another insulation monitoring device designated in advance when the multiple insulation monitoring devices are connected to one another as shown above in FIG. 6A.

Referring to FIG. 6B, the control unit 100 of the insulation monitoring device 10 according to an embodiment of the present disclosure may limit the driving of the signal generation unit 130 when a calculation notification signal is not received from another insulation monitoring device designated in advance (S600). In this case, the control unit 100 may deactivate the signal generation unit 130 so as to prevent a voltage according to a pulse signal from flowing into the ground PE 60. Here, the calculation notification signal may be a signal notifying that the other pre-designated insulation monitoring device has calculated the insulation resistance. Additionally, a state in which the signal generation unit 130 is inactive may be a state in which the signal generation unit 130 does not output a pulse signal.

While the driving of the signal generation unit 130 is limited, the control unit 100 may check whether the notification signal has been received from the other pre-designated insulation monitoring device through the interface 106 (S602). Furthermore, as a result of the check in step S602, a state in which the driving of the signal generation unit 130 is limited may be maintained until the notification signal is received.

Meanwhile, if the notification signal is received as a result of the check in the step S602, the control unit 100 may control the signal generation unit 130 so as to allow an operation state of the signal generation unit 130 to be switched to an activated state (S604). Here, the activation state of the signal generation unit 130 may be a state in which the signal generation unit 130 is driven to output a pulse signal with a normally stored positive or negative voltage.

When the signal generation unit 130 is activated to output a pulse signal according to the step S604, the control unit 100 may detect whether a voltage between an internal line to which the insulation monitoring device is connected and the ground 60 has been stabilized through the signal measurement unit 120. Furthermore, when the voltage between the internal line and the ground 60 is stabilized, a primary insulation resistance between the internal line and the ground 60 may be calculated based on the stabilized voltage (steady-state voltage).

Furthermore, when the primary insulation resistance is calculated, the control unit 100 may control the signal generation unit 130 so as to allow the polarity of the output pulse signal to be reversed, detect whether the voltage between the internal line to which the insulation monitoring device is connected and the ground 60 is stabilized through the signal measurement unit 120, and calculate a secondary insulation resistance based on the detected stabilized voltage (steady-state voltage). Furthermore, based on the calculated primary insulation resistance and secondary insulation resistance, a final insulation resistance between the internal line and the ground 60 may be calculated. As an example, the control unit 100 may calculate an average of the primary insulation resistance and the secondary insulation resistance to calculate the final insulation resistance (S606).

Here, the control unit 100 may change the polarity of the pulse voltage as well as the primary and secondary insulation resistances to calculate the final insulation resistance, and further calculate a preset number of additional insulation resistances. Furthermore, an average of the calculated insulation resistances may be calculated to calculate the final insulation resistance.

In the following description, the ‘process of calculating an insulation resistance’ may refer to ‘a process of calculating a preset number of insulation resistances according to a voltage of a pulse signal applied to an internal line through an activated signal generation unit 130, and finally calculating an insulation resistance between the internal line and the ground based on an average of the insulation resistances calculated in the preset number’.

When the calculation process of the insulation resistance is completed in the step S606, the control unit 100 may control the interface 106 to output a calculation notification signal for notifying that the insulation resistance calculation of itself (e.g., insulation monitoring device 10) has been completed to another pre-designated insulation monitoring device (S608). Furthermore, when the calculation notification signal is output, the process proceeds to step S600 again to deactivate the signal generation unit 130, thereby limiting the driving of the signal generation unit 130. Furthermore, the process may proceed to the S602 step to maintain the signal generation unit 130 in a deactivated state. Furthermore, based on a result of the check in the step S602, a process subsequent to step S604 of activating the signal generation unit 130 to calculate the insulation resistance may be performed.

Meanwhile, while the insulation resistance is calculated in the insulation monitoring device 10, the driving of the signal generation units in the other insulation monitoring devices constituting the insulation monitoring system according to an embodiment of the present disclosure may be in a limited state (e.g., the step S600). Furthermore, among the other insulation monitoring devices, one insulation monitoring device that has received a calculation notification signal from the insulation monitoring device 10 through the step S608 may perform a process of activating a signal generation unit, and calculating an insulation resistance based on a pulse signal output from the activated signal generation unit (e.g., the steps S604 to S606). Furthermore, when the insulation resistance is calculated, a calculation notification signal may be output to still another insulation monitoring device, and the signal generation unit may be deactivated again and the signal generation unit may be maintained in a deactivated state.

Accordingly, each interconnected insulation monitoring device may sequentially calculate an insulation resistance between an internal line connected by itself and the ground 60 according to a preset sequence. In this case, as described above, while one insulation monitoring device is calculating an insulation resistance, the driving of the signal generation units in the other insulation monitoring devices is limited. Therefore, only a voltage of a pulse signal applied from an insulation monitoring device that calculates an insulation resistance is applied to the ground 60, and also, internal resistances of the other insulation monitoring devices are ignored due to a resistance magnitude of the multi-winding transformer 70, and thus multiple insulation monitoring devices connected to the same ground 60 (multiple insulation monitoring devices constituting an insulation monitoring system) may calculate an insulation resistance between an internal line connected by itself and the ground 60 without measurement interference between the insulation monitoring devices.

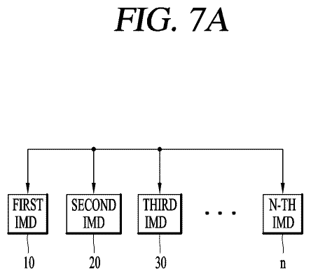

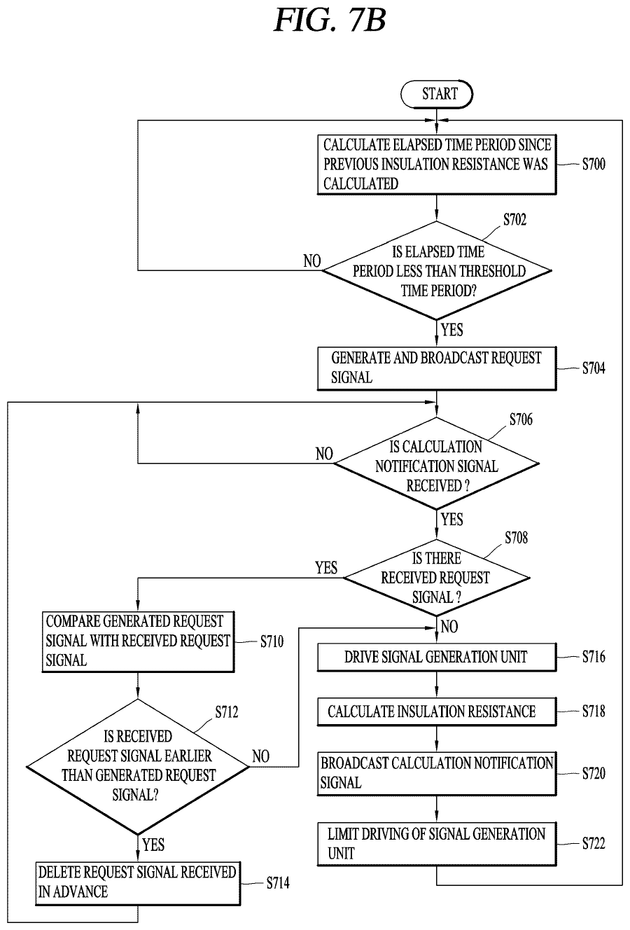

Meanwhile, FIG. 7A shows an example in which multiple insulation monitoring devices constituting the insulation monitoring system configure a bus-structured network topology. Furthermore, FIG. 7B is a flowchart showing an operation process of controlling, by each insulation monitoring device, the driving of a signal generation unit and calculating an insulation resistance based on an calculation notification signal received from another insulation monitoring device when a bus network topology is configured in this manner.

First, referring to FIG. 7A, FIG. 7A shows an example of a network in the form of a bus in which multiple insulation monitoring devices constituting the insulation monitoring system share one transmission line. In this case, since all insulation monitoring devices are connected to one transmission line as shown in FIG. 7A, a signal output from one insulation monitoring device may be received by all insulation monitoring devices (broadcasting).

Accordingly, each insulation monitoring device may broadcast, when the calculation of the insulation resistance is required, a request signal indicating that the calculation of the insulation resistance is required to all insulation monitoring devices sharing the transmission line. Additionally, each insulation monitoring device may broadcast, when its own insulation resistance calculation is completed, a calculation notification signal to all insulation monitoring devices sharing the transmission line indicating that the calculation of the insulation resistance is completed. Then, each insulation monitoring device that has received the calculation notification signal may determine whether to calculate the insulation resistance based on a time point at which the request signal has been broadcast by itself and a time point at which the request signal has been received from another insulation monitoring device, and activate the signal generation unit to calculate the insulation resistance.

FIG. 7B is a flowchart showing an operation process of controlling, by each insulation monitoring device, the driving of a signal generation unit and calculating an insulation resistance based on an calculation notification signal received from another insulation monitoring device when a bus network topology is configured in this manner.

Referring to FIG. 7B, the control unit 100 of the insulation monitoring device 10 according to an embodiment of the present disclosure may calculate a time period elapsed from a time point at which the previous insulation resistance was calculated while the driving of the signal generation unit 130 is limited (S700). Furthermore, it may be possible to check whether the elapsed time period is above a preset threshold time period (S702). Furthermore, as a result of the check in the step S702, when the time period elapsed from the time point when the previous insulation resistance was calculated is less than the preset threshold time period, the driving of the signal generation unit 130 may be maintained in a limited state.

On the contrary, when a result of the check in the step S702 shows that the elapsed time period is above the preset threshold time period, the control unit 100 may determine that the calculation of the insulation resistance is necessary. Therefore, a request signal may be generated to notify other insulation monitoring devices constituting the insulation monitoring system that the calculation of an insulation resistance is required, and the generated request signal may be broadcast (S704). In this case, the control unit 100 may store information at a time point at which the request signal was broadcast.

Meanwhile, when the request signal is broadcast, the control unit 100 may check whether a broadcast calculation notification signal has been received from one of the other insulation monitoring devices constituting the insulation monitoring system through the interface 106 (S706). Furthermore, it may wait until the calculation notification signal is received.

Furthermore, when a result of the check in the step S706 shows that the calculation notification signal has been received, it may be detected whether a request signal broadcast from at least one of the other insulation monitoring devices has been received (S708). Furthermore, when, as a result of the detection in the step S708, a request signal broadcast from at least one of the other insulation monitoring devices is received, a time point at which the request signal generated by the control unit 100 is broadcast in the step S704 and a time point at which the request signal received from the at least one other insulation monitoring device may be compared with each other (S710). In this case, if there are multiple request signals received from the other insulation monitoring devices, the control unit 100 may compare a time point of reception of the earliest received request signal and a time point of broadcasting the request signal generated by the control unit 100 among the multiple request signals received from the other insulation monitoring devices.

As a result of the comparison in the step S710, it may be possible to determine whether a time point of reception of the request signal received from another insulation monitoring device is earlier than a time point of broadcasting the request signal generated by the control unit 100 (S712). Furthermore, when a result of the determination in the step S712 shows that a time point of reception of the request signal received from another insulation monitoring device is earlier than a time point of broadcasting the request signal generated by the control unit 100, the control unit 100 may proceed to step S706 to wait again until a calculation notification signal is received from another insulation monitoring device without calculating the insulation resistance. Then, one of the other insulation monitoring devices that has broadcast the request signal may drive the signal generation unit and calculate the insulation resistance according to the calculation notification signal received through the broadcasting.

When waiting again until a calculation notification signal is received from another insulation monitoring device without calculating the insulation resistance, the control unit 100 may delete a request signal whose reception time point is earlier than a time point at which the request signal generated by the control unit 100 is broadcast (S714). In this case, when there are multiple request signals whose reception time point is earlier than a time point at which the request signal generated by the control unit 100 is broadcast, the request signal with the earliest reception time point may be deleted.

Meanwhile, when a result of the check in the step S706 shows that the calculation notification signal is received, the control unit 100 may detect again whether there is a request signal received from another insulation monitoring device in step S708. Furthermore, according to a result of the detection in step S708, the process proceeds to steps S710 and S712 to compare a time point at which a request signal has been received from another insulation monitoring device and a time point at which the request signal generated by the control unit 100 has been broadcast.

Meanwhile, when as a result of the comparison between the steps S710 and S712, a time point at which the request signal generated by the control unit 100 is broadcast is earlier than a time point at which at least one request signal is received from at least one other insulation monitoring device, the control unit 100 may control the signal generation unit 130 so as to allow the signal generation unit 130 to be activated (S716). Here, the control unit 100 may delete information on a time point at which the request signal generated by the control unit 100 is broadcast.

Furthermore, the control unit 100 may calculate an insulation resistance between an internal line to which the insulation monitoring device 10 is connected and the ground 60 based on a voltage of a pulse signal output from the activated signal generation unit 130 (S718). Furthermore, when the calculation of the insulation resistance is completed, the control unit 100 may transmit (broadcast) a calculation notification signal to all insulation monitoring devices constituting the insulation monitoring system to notify that the calculation of the insulation resistance of itself, that is, the insulation monitoring device 10, has been completed (S720). Furthermore, the signal generation unit 130 may be controlled to switch back to an inactive state (S722). Therefore, when the calculation of the insulation resistance is completed, a pulse signal output of the signal generation unit 130 may be stopped.

Then, the control unit 100 may proceed to step S700 to calculate a time period elapsed from a time point at which the insulation resistance is calculated. Furthermore, based on the calculated elapsed time period, a request signal may be broadcast to indicate that the calculation of an insulation resistance is required (step S704), and the process proceeds to step S706 to check whether there is a calculation notification signal received from another insulation monitoring device. Furthermore, depending on whether the calculation notification signal is received, the process subsequent to step S708 may be performed again. Therefore, the signal generation unit 130 may be maintained in an inactive state until the insulation resistance is calculated upon receipt of the calculation notification signal.

Meanwhile, when a result of the detection in the step S708 shows that there is no request signal received from another insulation monitoring device, the control unit 100 may proceed directly to step S716 to switch the signal generation unit 130 to an activated state. Furthermore, according to the process subsequent to step S716, the insulation resistance may be calculated, and a calculation notification signal indicating that the calculation of the insulation resistance has been completed may be broadcast, and the signal generation unit 130 may be switched back to an inactive state. Furthermore, the control unit 100 may proceed to step S700 to perform a subsequent process again.

When multiple insulation monitoring devices are connected through a bus network in this manner, the multiple insulation monitoring devices may determine whether the calculation of an insulation resistance is necessary based on a time period elapsed from a time point at which the previous insulation resistance was calculated, and broadcast, when the calculation of the insulation resistance is necessary, this through a request signal to notify other insulation monitoring devices. Furthermore, when there are already request signals received from other insulation monitoring devices, it may be possible to determine which insulation monitoring device must calculate an insulation resistance first by comparing time points at which the request signals were received. Furthermore, according to the determined priority, another insulation monitoring device with a higher priority, that is, an insulation monitoring device that has broadcast the request signal first, may wait to calculate the insulation resistance first. Accordingly, among multiple insulation monitoring devices, an insulation monitoring device that will more preferentially calculate an insulation resistance may be autonomously determined based on a time period elapsed from a time point at which the insulation resistance is calculated.

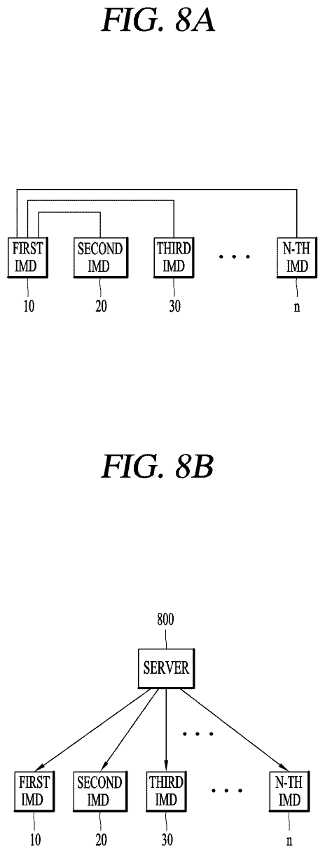

Meanwhile, FIGS. 8A and 8B show examples in which a sequence in which each insulation monitoring device calculates an insulation resistance is determined by one of multiple insulation monitoring devices or a separate higher system (e.g., a server).

First, referring to FIG. 8A, an insulation monitoring system according to an embodiment of the present disclosure may be connected one-to-one with one insulation monitoring device constituting the insulation monitoring system. In this case, the multiple insulation monitoring devices may constitute a star network in which other insulation monitoring devices, that is, multiple slave devices, are connected to the one insulation monitoring device, that is, a master device (e.g., first IMD 10).

In this case, the master device may determine a sequence in which each of the multiple slave devices calculates an insulation resistance. In this case, the insulation resistance calculation sequence may be determined according to a priority of each of the multiple slave devices.

In this case, the master device may control each slave device to calculate an insulation resistance in a sequence according to the priority. As an example, the master device may receive, when an insulation resistance is calculated from one slave device, a calculation notification signal from the slave device. Furthermore, the received calculation notification signal may be transmitted to a slave device in a next sequence according to the priority. Then, the slave device that has received the calculation notification signal may activate the signal generation unit and calculate the insulation resistance according to the reception of the calculation notification signal. Furthermore, the calculation notification signal may be transmitted back to the master device.

Meanwhile, the master device may calculate an insulation resistance by itself according to a preset priority when a calculation notification signal is received from one slave device. Furthermore, when the calculation of the insulation resistance is completed, a calculation notification signal may be transmitted to a slave device in a next sequence according to the priority. Here, the priority may be preset for each insulation monitoring device, or determined according to a time period elapsed from a time point at which each insulation monitoring device lastly calculated the insulation resistance. In this case, the longer the time period elapsed from the time point at which lastly calculated the insulation resistance, the higher the priority may be set. Therefore, the insulation resistance may be first calculated.

Meanwhile, in FIG. 8A, an example in which one of multiple insulation monitoring devices constituting an insulation monitoring system is set as a master device has been described, but in addition to the multiple insulation monitoring devices constituting the insulation monitoring system, a higher system, that is, another device or apparatus, may, of course, also manage and control the insulation resistance calculation sequence. In such a case, an insulation monitoring system according to an embodiment of the present disclosure may be configured to include the higher system in addition to multiple insulation monitoring devices.

FIG. 8B shows an example of such an insulation monitoring system, in which multiple insulation monitoring devices constituting the insulation monitoring system sequentially calculate insulation resistances under the control of a higher system, for example, a server 800.

Referring to FIG. 8B, in an insulation monitoring system according to an embodiment of the present disclosure, each insulation monitoring device constituting the insulation monitoring system and a preset server 800 may be connected one-to-one. In this case, the multiple insulation monitoring devices may constitute a star network in which multiple slave devices are connected to the server 800 that performs the role of a master device.

In this case, the server 800 may determine a sequence in which each of the multiple slave devices calculates an insulation resistance. In this case, the insulation resistance calculation sequence may be determined according to a priority of each of the multiple slave devices.

Furthermore, the server 800 may control each slave device to calculate an insulation resistance in a sequence according to the priority. As an example, the server 800 may receive, when an insulation resistance is calculated from one slave device, a calculation notification signal from the slave device. Furthermore, the received calculation notification signal may be transmitted to a slave device in a next sequence according to the priority. Then, the slave device that has received the calculation notification signal may activate the signal generation unit and calculate the insulation resistance according to the reception of the calculation notification signal. Furthermore, the calculation notification signal may be transmitted back to the server 800.

Meanwhile, in the foregoing description, an example in which multiple insulation monitoring devices constituting the insulation monitoring system are connected in a specific network form has been described, but the multiple insulation monitoring devices may, of course, also be connected to one another through multiple different forms of networks. In this case, a signal for determining an insulation resistance calculation sequence and a calculation notification signal may be respectively transmitted through different networks.

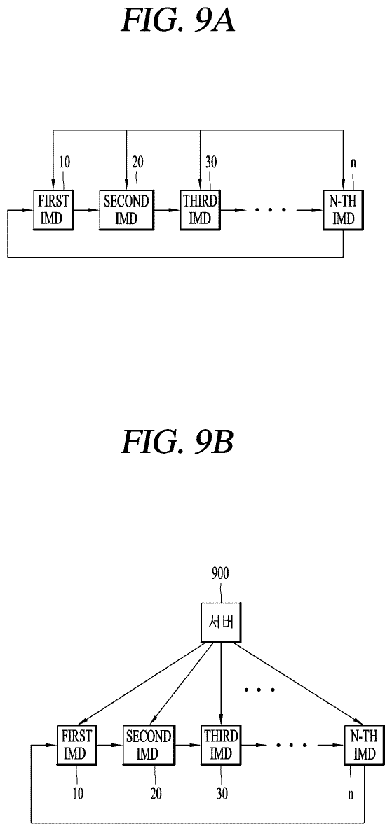

FIGS. 9A and 9B show examples in which multiple insulation monitoring devices are connected to one another through multiple different forms of networks in this manner.

First, referring to FIG. 9A, multiple insulation monitoring devices according to an embodiment of the present disclosure may be connected in a composite form of a ring network and a bus network. In this case, each insulation monitoring device may be connected to two adjacent insulation monitoring devices according to their placement locations on the network to constitute a first network. In this case, the first network may be a ring network.

Meanwhile, each of the insulation monitoring devices may be connected to a second network that shares a transmission line separate from the first network. In this case, the second network may be a bus network.

When multiple insulation monitoring devices are connected to one another through the first network and the second network in this manner, different signals may be transmitted to the first network and the second network. For example, the second network may be a network in which each insulation monitoring device transmits a request signal generated according to a time period elapsed from a time point at which the previous insulation resistance was calculated. That is, each insulation monitoring device may broadcast, when a threshold time period has elapsed from a time point at which the previous insulation resistance was calculated, a request signal notifying that the calculation of an insulation resistance is necessary to all insulation monitoring devices through the second network.

Meanwhile, the first network may be a network in which a calculation notification signal is transmitted when each insulation monitoring device completes the calculation of the insulation resistance. In this case, an insulation monitoring device that has received the calculation notification signal through the first network may determine whether it is a time point that is required to calculate an insulation resistance (when a time point at which a request signal generated by itself is broadcast is the earliest) by comparing a time point at which a request signal generated by itself is broadcast and a time point at which a request signal is received from other insulation monitoring devices, as described above in FIG. 7B. Furthermore, when it is a time point that is not required to calculate an insulation resistance, the received calculation notification signal may be transmitted to another insulation monitoring device without calculating the insulation resistance. However, when it is a time point that is required to calculate the insulation resistance as a result of the determination, the insulation resistance may be calculated by itself when the calculation notification signal is received through the first network. Furthermore, the device may output the calculation notification signal to an insulation monitoring device in a next sequence adjacent thereto.

Meanwhile, FIG. 9A shows that multiple insulation monitoring devices determine whether it is a time point that is required to calculate an insulation resistance on their own according to a broadcast request signal and calculate an insulation resistance based on a result of the determination. However, the master server 900 may, of course, also directly designate a calculation sequence of the insulation resistance. FIG. 9B shows an example of such a case.

Referring to FIG. 9B, multiple insulation monitoring devices according to an embodiment of the present disclosure may be connected in a composite form of a ring network and a star network. In this case, an insulation monitoring system according to an embodiment of the present disclosure may further include a master server 900 as well as multiple insulation monitoring devices.

Furthermore, each insulation monitoring device may be connected to two adjacent insulation monitoring devices according to their network placement locations to constitute a first network. In this case, the first network may be a ring network, and a sequence in which a signal is received through the first network may be determined between adjacent insulation monitoring devices connected to each insulation monitoring device according to their locations disposed on the network.

Meanwhile, the each insulation monitoring device may be connected to a second network that is directly connected to a preset master server 900, separately from the first network. In this case, the second network may be a star network.

When multiple insulation monitoring devices are connected to one another through the first network and the second network in this manner, different signals may be transmitted to the first network and the second network. For example, the second network may be a network in which an initiation signal for initiating the calculation of an insulation resistance according to an insulation resistance calculation sequence determined by the master server 900 is transmitted from the master server 900 to each insulation monitoring device. In this case, the master server 900 may determine an insulation monitoring device to calculate an insulation resistance according to a preset sequence, and transmit the initiation signal to the determined one insulation monitoring device.

Meanwhile, the first network may be a network in which a calculation notification signal is transmitted when each insulation monitoring device completes the calculation of the insulation resistance. In this case, the insulation monitoring device that has received the calculation notification signal through the first network may check whether an initiation signal has been received from the master server 900. Furthermore, when the initiation signal is not received, the received calculation notification signal may be transmitted to another insulation monitoring device without calculating the insulation resistance. However, when a result of the check shows that the initiation signal has been received from the master server 900, the device itself may calculate the insulation resistance when a calculation notification signal is received through the first network. Furthermore, the device may output the calculation notification signal to an insulation monitoring device in a next sequence adjacent thereto. Furthermore, the signal generation unit may be switched back to a deactivated state and maintained in a state of being switched in the deactivated state.

Then, the insulation monitoring device in a next sequence that has received the calculation notification signal may check whether the initiation signal transmitted by the master server 900 has been received. Furthermore, when the initiation signal has not been received, the calculation notification signal may be transmitted to an insulation monitoring device in a next sequence. However, when the calculation notification signal has been received through the first network while the initiation signal has been received by the master server 900 through the second network, the insulation monitoring device that has received the calculation notification signal may activate the signal generation unit to calculate an insulation resistance. Accordingly, multiple insulation monitoring devices may sequentially calculate insulation resistances according to a sequence set by the master server 900.

Meanwhile, in the foregoing description, an example in which different insulation monitoring devices are respectively connected to different internal lines separated by the multi-winding transformer 70 has been described. However, one or more insulation monitoring devices may, of course, also be disposed on the same internal line to monitor insulation states for different areas of the internal line.

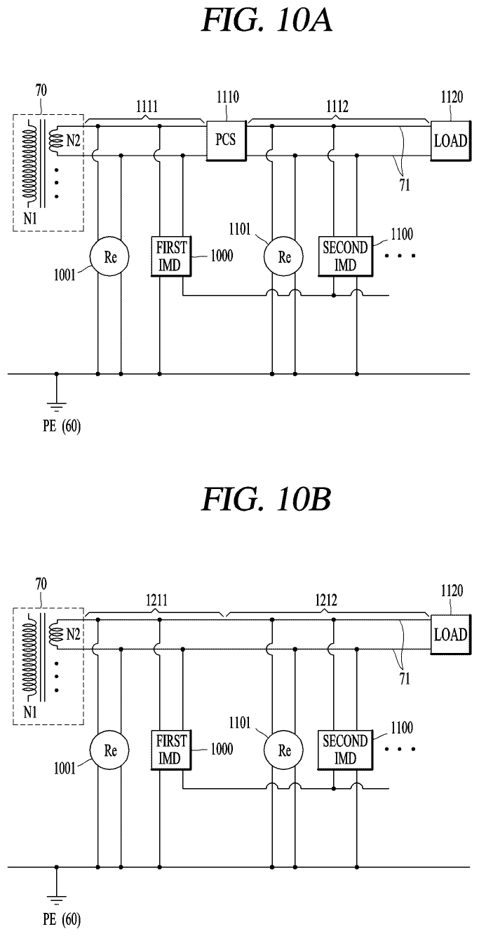

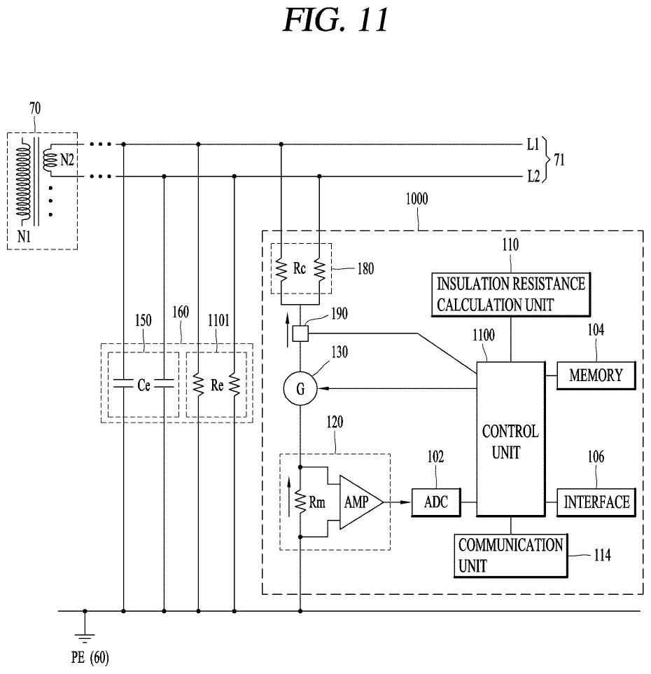

FIGS. 10A to 11 show examples of such cases.

First, referring to FIG. 10A, even if it is one internal line linked to the multi-winding transformer 70, it may be divided into different sections in which the component of a current flowing therethrough changes depending on the type of a load 1120 connected to the internal line 71. For example, when the load 1120 is a load that uses a direct current, such as an energy storage system (ESS), a battery, or a photovoltaic (PV) generator, a power conditioning system (PCS) 1110 for converting an alternating current of a power line into a direct current may be provided in the internal line 71.

Furthermore, in the case where the power conditioning system (PCS) 1110 is provided on the internal line 71 in this manner, a section prior to the power conditioning device 1110 (a section 1111 between the multi-winding transformer 70 and the power conditioning device 1110) may be a section in which a current whose current component is not converted by the power conditioning device 1110, that is, an alternating current, may flow, and a section subsequent to the power conditioning device 1110 (a section 1112 from the multi-winding transformer 70 to the load 1120) may be a section in which a current whose current component is converted by the power conditioning device 1110, that is, a direct current, may flow. Furthermore, when the internal line 71 is divided into multiple sections in this manner, insulation monitoring may be required for each section. Accordingly, as shown in FIG. 10A, a first insulation monitoring device 1000 may be disposed, which is connected to the internal line 71 corresponding to an alternating current section 1111 and the ground 60, and calculates an insulation resistance (first insulation resistance 1001) between the internal line 71 corresponding to the alternating current section 1111 and the ground 60. In addition, a second insulation monitoring device 1100 may be disposed, which is connected to the internal line 71 corresponding to a direct current section 1112 and the ground 60, and calculates an insulation resistance (second insulation resistance 1101) between the internal line 71 corresponding to the direct current section 1112 and the ground 60.

In this case, the locations where the first insulation monitoring device 1000 and the second insulation monitoring device 1100 are connected to the ground 60, which are adjacent locations where a sufficient distance is not secured, may be connected to the same ground 60. That is, the first insulation monitoring device 1000 and the second insulation monitoring device 1100 may constitute an insulation monitoring system connected to the same ground 60.

Meanwhile, in the case of FIG. 10A, an example in which the internal line 71 is divided into multiple areas by the power conditioning system 1110 has been described, but even in the absence of the power conditioning device 1110, multiple power conditioning systems may, of course, also be provided in one internal line 71 if necessary. In this case, the multiple power conditioning systems may each perform insulation monitoring for different sections of the internal line 71. FIG. 10B shows an example of such a case.

Referring to FIG. 10B, FIG. 10B shows an example in which multiple insulation monitoring devices 1000, 1100 are disposed in one internal line 71.

Referring to FIG. 10B, FIG. 10B shows that insulation monitoring devices (first insulation monitoring device 1000, second insulation monitoring device 1100) connected to the internal line 71 and the ground 60 may be disposed at different locations of the internal line 71.

In this case, the first insulation device 1000 may calculate an insulation resistance (first insulation resistance 1001) between a first section 1211 of the internal line 71 and the ground 60. Additionally, the second insulation device 1100 may calculate an insulation resistance (second insulation resistance 1101) between a second section 1212 of the internal line 71 and the ground 60.

Meanwhile, the first insulation monitoring device 1000 and the second insulation monitoring device 1100 examined above in FIGS. 10A and 10B are insulation monitoring devices connected to one internal line 71, and when one insulation monitoring device calculates an insulation resistance regardless of a resistance of the multi-winding transformer 70, the internal resistance Rm of the other insulation monitoring device may be combined with the insulation resistance Re.

In this case, since both the insulation resistance Re and the internal resistance Rm have a magnitude of several thousand ohms, there is a problem in that the internal resistance Rm cannot be ignored. Accordingly, multiple insulation monitoring devices connected to one internal line in this manner may further include a changeover element for temporarily changing over an insulation monitoring device that does not calculate an insulation resistance from the internal line, in addition to deactivating a signal generation unit, in order to avoid measurement interference due to the internal resistance.

FIG. 11 is a block diagram showing a configuration of an insulation monitoring device 1000 further including a changeover element that can be changed over, when connected to one internal line as described above, from the internal line to avoid measurement interference with other insulation monitoring devices.

Referring to FIG. 11, the insulation monitoring device 1000 according to an embodiment of the present disclosure may be configured to further include a coupler resistor Rc 180 connected to each of power lines L1, L2 of an internal line 71, a signal generation unit 130, a signal measurement unit 120 including a detection resistor Rm, an ADC 102 that converts a voltage measured by the signal measurement unit 120 into a digital value, a control unit 100 that detects a steady-state voltage according to the applied pulse signal, an insulation resistance calculation unit 110, a memory 104 and an interface 106, as well as a changeover unit 190.

The changeover unit 190 may include a changeover element for changing over a connection between the signal generation unit 130 and the internal line 71. Here, the changeover element may be an electromagnetic contactor controlled using an electromagnet. In this case, the changeover element may consist of a magnetic switch or a magnetic contactor.

Meanwhile, the changeover unit 190 may have a first contact disposed on a side of the signal generation unit 130 and a second contact disposed on a side of the internal line 71. Furthermore, at least one of the first contact and the second contact may be formed of an electromagnet that generates a magnetic force under the control of the control unit 100. Accordingly, when a current is supplied to one of the contacts formed of the electromagnet, the first contact and the second contact may come into contact with each other, and thus a circuit between the signal generation unit 130 and the internal line 71 may be closed.

On the contrary, if a current supplied to one of the contacts formed of the electromagnet is interrupted, the first contact and the second contact may be separated from each other, and thus the circuit between the signal generation unit 130 and the internal line 71 may be opened. That is, the signal generation unit 130 may be changed over from the internal line 71.

In more detail, the control unit 100 may control the changeover unit 190 to transfer the signal generation unit 130 from the internal line 71 when the signal generation unit 130 is deactivated. Then, a circuit connecting the internal line 71 and the ground 60 through the insulation resistor 1101, the insulation capacitor 150, and the insulation monitoring device 1000 may be opened.

Therefore, when another insulation monitoring device (e.g. second insulation monitoring device 1100) calculates an insulation resistance, measurement interference caused by the internal resistance Rm of the first insulation monitoring device 1000 may be prevented due to an opening in the circuit.

On the contrary, when the signal generation unit 130 is activated, the control unit 100 may control the changeover unit 190 to bring a first contact on a side of the signal generation unit 130 into contact with a second contact on a side of the internal line 71. Then, the signal generation unit 130 and the internal line 71 may be reconnected. Accordingly, a pulse signal output from the activated signal generation unit 130 may be applied to the internal line 71. Then, a voltage may be received by the signal measurement unit 120 through a circuit connecting the internal line 71 and the ground 60 by way of the insulation resistor 1101, the insulation capacitor 150, and the insulation monitoring device 1000. Therefore, the insulation resistance calculation unit 110 may calculate the insulation resistance 1101 based on the received voltage.

While the first insulation monitoring device 1000 calculates the insulation resistance 1101, another insulation monitoring device, for example, the second insulation monitoring device 1100, may deactivate the signal generation unit. Furthermore, a contact between the first contact and the second contact may be released by controlling the changeover unit. Then, the signal generation unit may be changed over from the internal line 71, and the circuit may be opened to prevent measurement interference due to the internal resistance Rm of the second insulation monitoring device 1100.

The changeover unit 190 may be driven only when an insulation resistance is calculated between insulation monitoring devices disposed on the same internal line. That is, when the insulation monitoring devices connected to different internal lines 71, 72 calculate an insulation resistance, the control unit 100 may not drive the changeover unit 190.

Meanwhile, in the foregoing description, an example in which the changeover unit 190 is disposed to connect between the signal generation unit 130 and the internal line 71 or to separate the signal generation unit 130 from the internal line 71 has been described, but the changeover unit 190 may, of course, also control a connection between the other elements of the insulation monitoring device 1000 and the internal line 71.

As an example, the changeover unit 190 may be disposed between the signal measurement unit 120 and the ground 60 to separate the signal measurement unit 120 from the ground 60 or connect the separated signal measurement unit 120 to the ground 60.

The foregoing present disclosure may be implemented as computer-readable codes on a program-recorded medium. The computer-readable medium includes all kinds of recording devices in which data readable by a computer system is stored. Examples of the computer-readable medium include a hard disk drive (HDD), a solid state disk (SSD), a silicon disk drive (SDD), a ROM, a RAM, a CD-ROM, a magnetic tape, a floppy disk, an optical data storage device and the like, and also include a device implemented in the form of a carrier wave (for example, transmission via the Internet). Therefore, the detailed description should not be limitedly construed in all of the aspects, and should be understood to be illustrative. The scope of the present disclosure should be determined by reasonable interpretation of the appended claims and all changes that come within the equivalent scope of the present disclosure are included in the scope of the present disclosure.

1. An insulation monitoring system comprising multiple insulation monitoring devices, each of which:
maintains in a deactivated state a signal generation unit that applies a pulse signal to at least one internal line connected to a power line through a transformer, and detects the reception of a preset notification signal from at least one other insulation monitoring device that is communicably connected thereto;
activates, when the notification signal is received as a result of the detection, the signal generation unit in the deactivated state so as to allow a pulse signal to be applied to the one internal line;
calculates an insulation resistance between the one internal line and the ground according to the pulse signal applied to the one internal line from the activated signal generation unit; and
transmits, when the insulation resistance is calculated, the notification signal to the at least one other insulation monitoring device that is communicably connected thereto, and switches the activated signal generation unit back to an inactive state.

2. The system of claim 1, wherein the insulation monitoring device comprises:
an interface unit that performs a communication connection with the at least one other insulation monitoring device;
the signal generation unit;
a signal measurement unit connected to the ground to measure a voltage according to a pulse signal generated from the activated signal generation unit from the ground;
an insulation resistance calculation unit that calculates the insulation resistance based on the voltage measured by the signal measurement unit; and
a control unit that receives the notification signal from one of the at least one other insulation monitoring device through the interface unit, activates the signal generation unit when the notification signal is received, controls the insulation resistance calculation unit so as to allow the insulation resistance to be calculated, transmits the notification signal to the at least one other insulation monitoring device when the insulation resistance is calculated, and switches the signal generation unit to an inactive state.

3. The system of claim 2, wherein the signal generation unit comprises:
a power source circuit disposed to supply power to the signal generation unit according to the control of the control unit.

4. The system of claim 1, wherein the multiple insulation monitoring devices are multiple insulation monitoring devices sharing the same ground.

5. The system of claim 1, wherein the multiple insulation monitoring devices constitute a ring network in which adjacently arranged insulation monitoring devices are communicably connected to one another, and
wherein each of the multiple insulation monitoring devices activates, when the notification signal is received from a first insulation monitoring device adjacent thereto, a signal generation unit in a deactivated state to calculate an insulation resistance, switches, when the insulation resistance is calculated, the activated signal generation unit to a deactivated state, and transmits the notification signal to a second insulation monitoring device adjacent thereto.

6. The system of claim 1, wherein the multiple insulation monitoring devices constitute a bus network that shares one transmission line and is communicably connected to one another through the shared transmission line, and
wherein each of the multiple insulation monitoring devices receives the notification signal broadcast by one of the other insulation monitoring devices through the shared transmission line, calculates an insulation resistance by activating a signal generation unit in a deactivated state based on a time period elapsed from a time point at which the previous insulation resistance was calculated and a time point at which the notification signal was received, and switches, when the insulation resistance is calculated, the activated signal generation unit to a deactivated state, and broadcasts the notification signal to at least one other insulation monitoring device through the shared transmission line.

7. The system of claim 6, wherein each of the multiple insulation monitoring devices broadcasts a request signal indicating that the calculation of an insulation resistance is necessary to at least one other insulation monitoring device based on whether a time period elapsed from a time point at which the previous insulation resistance was calculated is above a threshold time period, and determines, when the notification signal is received, whether to activate the signal generation unit by comparing a time point at which the request signal was broadcast with a time point at which the request signal was received from at least one other insulation monitoring device until the notification signal is received.

8. The system of claim 1, wherein the multiple insulation monitoring devices constitute a star network in which each of the multiple insulation monitoring devices is connected to a preset master device, and
wherein the master device determines an insulation resistance calculation sequence of each of the multiple insulation monitoring devices according to a preset priority, receives the notification signal from one insulation monitoring device whose insulation resistance has been calculated, and transmits the received notification signal to an insulation monitoring device in a next sequence of the one insulation monitoring device according to the determined insulation resistance calculation sequence.

9. The system of claim 8, wherein the master device is one of the multiple insulation monitoring devices.

10. The system of claim 1, wherein the transformer is a multi-winding transformer that links multiple different internal lines to a single power line, and
wherein the multiple insulation monitoring devices are devices that monitor insulation states between the ground and multiple different internal lines connected to different windings of the multi-winding transformer.

11. The system of claim 1, wherein the transformer is a multi-winding transformer that links multiple different internal lines to a single power line, and
wherein the multiple insulation monitoring devices are devices that monitor insulation states between different points of an internal line connected to the same winding of the multi-winding transformer and the ground.

12. The system of claim 11, wherein the insulation monitoring device comprises:
a changeover unit that separates the insulation monitoring device from the internal line or connects the insulation monitoring device separated from the internal line to the internal line;
an interface unit that performs a communication connection with the at least one other insulation monitoring device;
the signal generation unit;
a signal measurement unit connected to the ground to measure a voltage according to a pulse signal generated from the activated signal generation unit from the ground;
an insulation resistance calculation unit that calculates the insulation resistance based on the voltage measured by the signal measurement unit; and
a control unit that receives the notification signal from one of the at least one other insulation monitoring device through the interface unit, controls, when the notification signal is received, the changeover unit to connect the separated insulation monitoring device to the internal line, and activate the signal generating unit, controls, when the signal generating unit is activated, the insulation resistance calculation unit so as to allow the insulation resistance to be calculated, transmits, when the insulation resistance is calculated, the notification signal to the at least one other insulation monitoring device, and controls the changeover unit so as to switch the signal generation unit to an inactive state and allow the insulation monitoring device to be separated from the internal line.

13. The system of claim 12, wherein the changeover unit is disposed to separate the signal generation unit from the internal line or reconnect the signal generation unit separated from the internal line back to the internal line, or to separate the signal measurement unit from the ground or to reconnect the signal measurement unit separated from the ground to the ground.

14. The system of claim 12, wherein the changeover unit has a first side disposed on a side of the signal generation unit or signal measurement unit, and a second side disposed on a side of the internal line or grounding, and comprises an electronic contactor in which the first side and the second side are in contact with each other when a current is supplied according to the control of the control unit, and the first side and the second side are separated from each other when the current supply is interrupted.

15. A method of controlling one of multiple insulation monitoring devices constituting an insulation monitoring system, the method comprising:
switching a signal generation unit that applies a pulse signal to one of at least one internal line linked to a power line through a transformer to a deactivated state;
maintaining the signal generation unit in a deactivated state until a preset notification signal is received from one of at least one other insulation monitoring device constituting the insulation monitoring system that are connected to one another while the signal generation unit is in a deactivated state;
switching, when the notification signal is received, the signal generation unit to an activated state;
calculating an insulation resistance between the one internal line and the ground according to the pulse signal applied to the one internal line from the activated signal generation unit;
transmitting, when the insulation resistance is calculated, the notification signal to the at least one other insulation monitoring device that is communicably connected thereto; and
repeating the steps of switching, when the notification signal is transmitted, the signal generation unit to a deactivated state, maintaining the signal generation unit in a deactivated state, activating the signal generation unit according to whether the notification signal is received, calculating the insulation resistance, and transmitting the notification signal.

16. The method of claim 15, wherein the transformer is a multi-winding transformer that links multiple different internal lines to a single power line, and
wherein the multiple insulation monitoring devices are devices that monitor insulation states between different points of an internal line connected to the same winding of the multi-winding transformer and the ground.

17. The method of claim 16, wherein the switching of the signal generation unit to a deactivated state further comprises:
separating the insulation monitoring device from the internal line, and
wherein the switching of the signal generation unit to an active state further comprises:
reconnecting the insulation monitoring device, which has been separated from the internal line, to the internal line.

18. The method of claim 15, wherein the notification signal is transmitted, when an insulation resistance is calculated from one insulation monitoring device, to an insulation monitoring device in a next sequence of the one insulation monitoring device based on an insulation resistance calculation sequence according to a priority set for each of the multiple insulation monitoring devices, and
wherein the priority is determined according to a time period elapsed from a time point at which each insulation monitoring device lastly calculated the insulation resistance.
